(19) United States
(12) Patent Application Publication
(10) Pub. No.: US 2017/0170304 A1
(43) Pub. Date: Jun. 15, 2017

(54) BIPOLAR JUNCTION TRANSISTOR AND METHOD OF MANUFACTURING THE SAME

(71) Applicant: DONGBU HITEK CO., LTD., Seoul (KR)

(72) Inventor: Joo Hyung Kim, Seoul (KR)

(21) Appl. No.: 15/370,154

(22) Filed: Dec. 6, 2016

(30) Foreign Application Priority Data
Dec. 10, 2015 (KR) 1020150175809

(51) Int. Cl. H01L 29/735; H01L 29/66; H01L 29/10; H01L 29/45; H01L 29/06; H01L 29/08

(52) U.S. Cl. CPC H01L 29/735; H01L 29/0649; H01L 29/0808; H01L 29/1008; H01L 29/0821; H01L 29/45; H01L 29/0692; H01L 29/6625

(57) ABSTRACT

A bipolar junction transistor includes a first well region having a first conductive type, a second well region disposed adjacent to the first well region and having a second conductive type, an emitter disposed on the first well region and having the second conductive type, a base disposed on the first well region and having the first conductive type, a collector disposed on the second well region and having the second conductive type, and device isolation regions disposed among the emitter, the base and the collector. Particularly, the emitter, the base and the collector are spaced apart from the device isolation regions.

### CROSS-REFERENCE TO RELATED APPLICATION

This application claims the priority benefit of Korean Patent Application No. 10-2015-0175809, filed on Dec. 10, 2015 and all the benefits accruing therefrom under 35 U.S.C. §119, the contents of which are incorporated by reference in their entirety.

### BACKGROUND

The present disclosure relates to a bipolar junction transistor and a method of manufacturing the same, and more particularly, to a bipolar junction transistor (BJT) having a reduced noise level and an improved current gain (hfe) and a method of manufacturing the same.

A bipolar junction transistor has a lower noise level than an MOSFET (Metal Oxide Semiconductor Field Effect Transistor). Further the bipolar junction transistor shows a wide range of linear gain and has excellent frequency response characteristics and current driving capability, and can be fabricated on the same substrate with a CMOS device for performing special high frequency functions.

Conventionally, the bipolar junction transistor includes an emitter, a base and a collector, and device isolation regions are disposed among the emitter, the base and the collector. The device isolation regions may be formed by a shallow trench isolation (STI) process.

However, because the STI stress effect and trap sites among the emitter, the base, the collector and the device isolation regions, the electrical noise of conventional bipolar junction transistors may be increased, and further the current gain of conventional bipolar junction transistors may be reduced.

### SUMMARY

The present disclosure provides a bipolar junction transistor having a reduced noise level and an improved current gain, and a method of manufacturing the same.

In accordance with an aspect of the present invention, a bipolar junction transistor may include a first well region having a first conductive type, a second well region disposed adjacent to the first well region and having a second conductive type, an emitter disposed on the first well region and having the second conductive type, a base disposed on the first well region and having the first conductive type, a collector disposed on the second well region and having the second conductive type, and device isolation regions disposed among the emitter, the base and the collector. Particularly, the emitter, the base and the collector may be spaced apart from the device isolation regions.

In accordance with some exemplary embodiments, the bipolar junction transistor may further include a first metal silicide pattern disposed on the emitter, a second metal silicide pattern disposed on the base, and a third metal silicide pattern disposed on the collector.

In accordance with some exemplary embodiments, the first metal silicide pattern may have a width equal to or smaller than that of the emitter.

In accordance with some exemplary embodiments, the second metal silicide pattern may have a width equal to or smaller than that of the base.

In accordance with some exemplary embodiments, the third metal silicide pattern may have a width equal to or smaller than that of the collector.

In accordance with some exemplary embodiments, the base may have a ring shape surrounding the emitter, and the collector may have a ring shape surrounding the base.

In accordance with some exemplary embodiments, the bipolar junction transistor may further include a deep well region having the second conductive type, and the first and second well regions may be disposed on the deep well region.

In accordance with some exemplary embodiments, the bipolar junction transistor may further include a third well region disposed adjacent to the second well region and having the first conductive type and a well tap disposed on the third well region and having the first conductive type.

In accordance with another aspect of the present invention, a method of manufacturing a bipolar junction transistor may include forming device isolation regions on a substrate, forming a first well region having a first conductive type on the substrate, forming a second well region having a second conductive type on the substrate to be adjacent to the first well region, forming a base having the first conductive type on the first well region, and forming an emitter and a collector having the second conductive type on the first and second well regions, respectively. Particularly, the emitter, the base and the collector may be formed among the device isolation regions to be spaced apart from the device isolation regions.

In accordance with some exemplary embodiments, the base may have a ring shape surrounding the emitter, and the collector may have a ring shape surrounding the base.

In accordance with some exemplary embodiments, the method may further include forming metal silicide patterns on the emitter, the base and the collector.

In accordance with some exemplary embodiments, the metal silicide patterns may be spaced apart from the device isolation regions.

In accordance with some exemplary embodiments, the method may further include forming a deep well region having the second conductive type in the substrate, and the first and second well regions may be formed on the deep well region.

In accordance with some exemplary embodiments, the method may further include forming an epitaxial layer having the first conductive type on the substrate, and the first and second well regions may be formed in the epitaxial layer.

In accordance with some exemplary embodiments, the substrate may have the first conductive type, and the first and second well regions may be formed in surface portions of the substrate.

In accordance with some exemplary embodiments, the method may further include forming a third well region having the first conductive type on the substrate to be adjacent to the second well region and forming a well tap having the first conductive type on the third well region. Particularly, the third well region may be simultaneously formed with the first well region, and the well tab may be simultaneously formed with the base.

The above summary is not intended to describe each illustrated embodiment or every implementation of the subject matter hereof. The figures and the detailed description that follow more particularly exemplify various embodiments.

### BRIEF DESCRIPTION OF THE DRAWINGS

Exemplary embodiments can be understood in more detail from the following description taken in conjunction with the accompanying drawings, in which:

FIG. 1 is a cross-sectional view illustrating a bipolar junction transistor (BJT) in accordance with an exemplary embodiment of the present invention;

FIG. 2 is a cross-sectional view illustrating a base, an emitter and a collector as shown in FIG. 1; and

FIGS. 3 to 8 are cross-sectional views illustrating a method of manufacturing the bipolar junction transistor as shown in FIG. 1.

While various embodiments are amenable to various modifications and alternative forms, specifics thereof have been shown by way of example in the drawings and will be described in detail. It should be understood, however, that the intention is not to limit the claimed inventions to the particular embodiments described. On the contrary, the intention is to cover all modifications, equivalents, and alternatives falling within the spirit and scope of the subject matter as defined by the claims.

### DETAILED DESCRIPTION OF THE DRAWINGS

Hereinafter, specific embodiments will be described in more detail with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art.

It will also be understood that when a layer, a film, a region or a plate is referred to as being ‘on’ another one, it can be directly on the other one, or one or more intervening layers, films, regions or plates may also be present. Unlike this, it will also be understood that when a layer, a film, a region or a plate is referred to as being ‘directly on’ another one, it is directly on the other one, and one or more intervening layers, films, regions or plates do not exist. Also, though terms like a first, a second, and a third are used to describe various components, compositions, regions and layers in various embodiments of the present invention are not limited to these terms.

In the following description, the technical terms are used only for explaining specific embodiments while not limiting the present invention. Unless otherwise defined herein, all the terms used herein, which include technical or scientific terms, may have the same meaning that is generally understood by those skilled in the art. In general, the terms defined in the dictionary should be considered to have the same meaning as the contextual meaning of the related art, and, unless clearly defined herein, should not be understood as abnormally or excessively formal meaning.

The embodiments of the present invention are described with reference to schematic diagrams of ideal embodiments of the present invention. Accordingly, changes in the shapes of the diagrams, for example, changes in manufacturing techniques and/or allowable errors, are sufficiently expected. Accordingly, embodiments of the present invention are not described as being limited to specific shapes of areas described with diagrams and include deviations in the shapes and also the areas described with drawings are entirely schematic and their shapes do not represent accurate shapes and also do not limit the scope of the present invention.

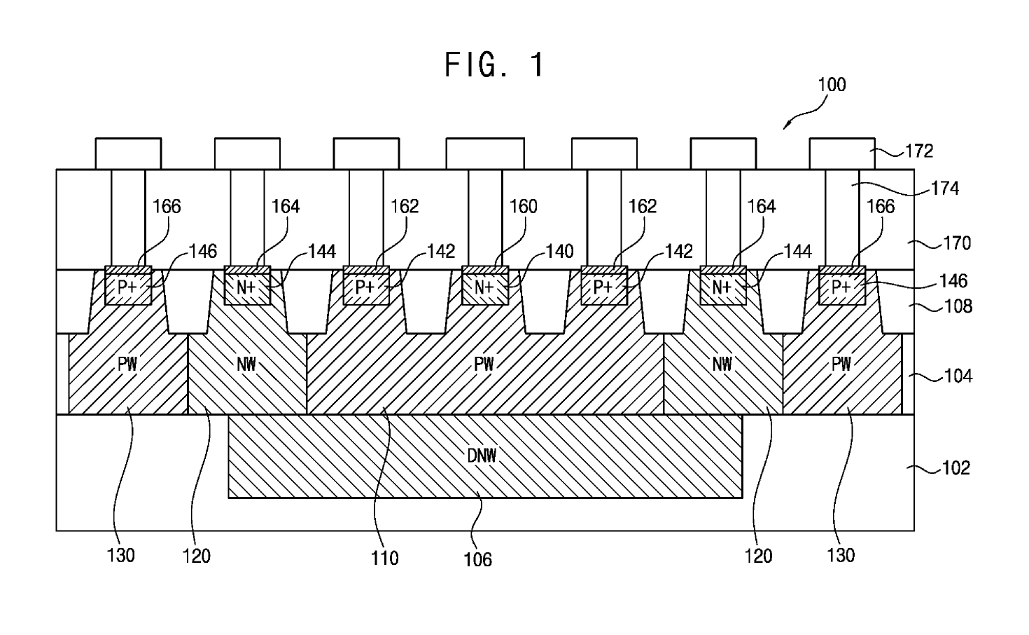

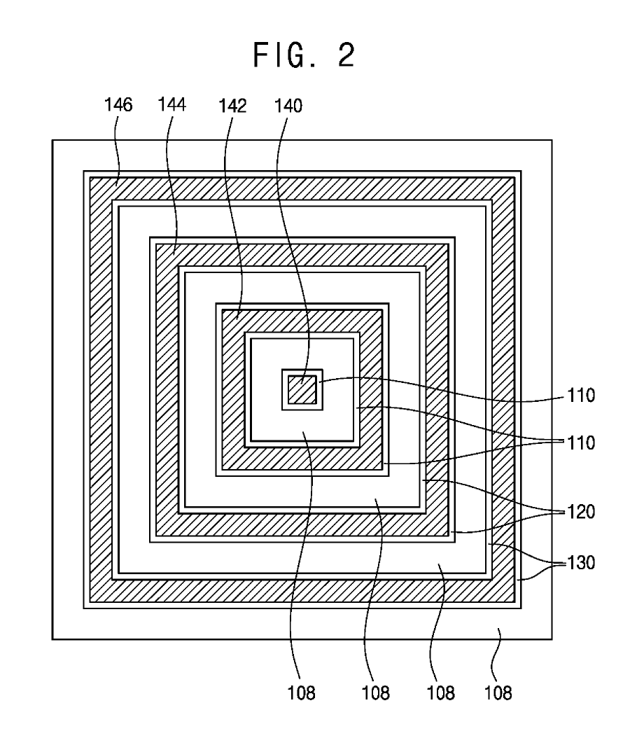

FIG. 1 is a cross-sectional view illustrating a bipolar junction transistor (BJT) in accordance with an exemplary embodiment of the present invention, and FIG. 2 is a cross-sectional view illustrating a base, an emitter and a collector as shown in FIG. 1.

Referring to FIGS. 1 and 2, a bipolar junction transistor 100, in accordance with an exemplary embodiment of the present invention, may include a first well region 110 of a first conductive type disposed in a substrate 102 and a second well region 120 of a second conductive type disposed adjacent to the first well region 110. For example, a p-type well (PW) region serving as the first well region 110 and an n-type well (NW) region serving as the second well region 120 may be formed in the substrate 102.

The substrate 102 may have the first conductive type. For example, a p-type substrate may be used as the substrate 102, and further a p-type epitaxial layer 104 may be formed on the substrate 102 by an epitaxial process. Particularly, when the p-type epitaxial layer 104 is formed on the substrate 102, the first and second well regions 110 and 120 may be formed in the p-type epitaxial layer. Alternatively, when the p-type substrate is used as the substrate 102, the first and second well regions 110 and 120 may be formed in surface portions of the substrate 102.

An emitter 140 of the second conductive type and a base 142 of the first conductive type may be disposed on the first well region 110. For example, a high concentration n-type impurity region serving as the emitter 140 and a high concentration p-type impurity region serving as the base 142 may be formed on the PW region 110.

A collector 144 of the second conductive type may be disposed on the second well region 120. For example, a second high concentration n-type impurity region serving as the collector 144 may be formed on the NW region 120. Particularly, the emitter 140 may be simultaneously formed with the collector 144.

In accordance with an exemplary embodiment of the present invention, the bipolar junction transistor 100 may include a deep well region 106 of the second conductive type disposed in the substrate 102, and the first and second well regions 110 and 120 may be disposed on the deep well region 106. For example, a deep n-type well (DNW) region serving as the deep well region 106 may be formed in the substrate 102, and the first and second well regions 110 and 120 may be formed on the DNW region. As a result, two PN junctions may be formed among the emitter 140, the first well region 110 and the deep well region 106. At this time, the first well region 110 may serve as a base region, and the deep well region 106 and the second well region 120 may serve as a collector region.

Further, a third well region 130 of the first conductive type may be disposed adjacent to the second well region 120, and a well tap 146 of the first conductive type may be disposed on the third well region 130. For example, a second p-type well (PW) region serving as the third well region 130 may be formed on side surfaces of the second well region 120, and a second high concentration p-type impurity region serving as the well tap 146 may be formed on the second PW region. The well tap 146 and the third well region 130 may be used to apply a bias voltage to the substrate 102. Further, the third well region 130 may be simultaneously formed with the first well region 110, and the well tap 146 may be simultaneously formed with the base 142.

In accordance with an exemplary embodiment of the present invention, the second well region 120 may have a ring shape surrounding the first well region 110, and the third well region 130 may have a ring shape surrounding the second well region 120. Particularly, the base 142 may have a ring shape surrounding the emitter 140, and the collector 144 may have a ring shape surrounding the base 142, as shown in FIG. 2. Further, the well tap 146 may have a ring shape surrounding the collector 146, and device isolation regions 108 may be each disposed among the emitter 140, the base 142, the collector 144 and the well tap 146.

As shown in FIG. 2, each of the rings is square in shape. One of skill in the art will recognize, however, that various alternative shapes could be used. For example, in alternative embodiments, each ring could be toroidal, or rectangular, or even an irregular shape. Nonetheless, in each embodiment, it is possible to separate emitter 140, base 142, collector 144, and well tap 146 from one another by appropriate placement of first well region 110, second well region 120, and third well region 130 or their equivalents.

In accordance with an exemplary embodiment of the present invention, the bipolar junction transistor 100 may include a first metal silicide pattern 160 disposed on the emitter 140, a second metal silicide pattern 162 disposed on the base 142, and a third metal silicide pattern 164 disposed on the collector 144. Further, the bipolar junction transistor 100 may include a fourth metal silicide pattern 166 disposed on the well tap 146. For example, cobalt silicide patterns may be used as the first, second, third and fourth metal silicide patterns 160, 162, 164 and 166.

In accordance with an exemplary embodiment of the present invention, the emitter 140, the base 142 and the collector 144 may be spaced apart from the device isolation regions 108. For example, the emitter 140 and the base 142 may be formed in upper surface portions of the first well region 110, and the collector 144 may be formed in an upper surface portion of the second well region 120, as shown in FIG. 1. As a result, the emitter 140, the base 142 and the collector 144 may be isolated from the device isolation regions 108 by the upper surface portions of the first and second well regions 110 and 120 when the bipolar junction transistor 100 is unbiased.

Further, the first metal silicide pattern 160 may have a width equal to or smaller than that of the emitter 140, the second metal silicide pattern 162 may have a width equal to or smaller than that of the base 142, and the third metal silicide pattern 164 may have a width equal to or smaller than that of the collector 144.

Still further, the well tap 146 may be spaced apart from the device isolation regions 108, and the fourth metal silicide pattern 166 may have a width equal to or smaller than that of the well tap 146. For example, the well tap 146 may be formed in an upper surface portion of the third well region 130, and thus the well tap 146 may be isolated from the device isolation regions 108 by the upper surface portion of the third well region 130.

As described above, the emitter 140, the base 142, the collector 144, and the well tap 146 may be spaced apart from the device isolation regions 108, and further the upper surface portions of the first, second and third well regions (110, 120 and 130, respectively) may be disposed among the emitter 140, the base 142, the collector 144 and the well tap 146. Thus, the electrical noise of the bipolar junction transistor 100, which may be caused by the STI induced stress, may be significantly reduced. Further, the electrons trapped in trap sites on side surfaces of the device isolation regions 108 may be reduced because the metal silicide portions (160, 162, 164, and 166) do not overlap with device isolation regions 108, as explained above. Thus the electron mobility may be improved between the emitter 140 and the collector 144. As a result, the current gain (hfe) of the bipolar junction transistor 100 may be significantly improved.

Meanwhile, an insulating layer 170 and a metal wiring layer 172 may be disposed on the bipolar junction transistor 100, as shown in FIG. 1. The metal wiring layer 172 may be connected with the bipolar junction transistor 100 by contact plugs 174. Although metal wiring layer 172 and contact plugs 174 are depicted only with respect to well tap 146 in FIG. 1, it should be understood that the structures extending from each of the emitter 140, base 142, and collector 144 are substantially equivalent structures, as shown in FIG. 1. Insulating layer 170 separates these structures from one another such that there is not direct electrical contact between the various metal wiring layers 172 and/or contact plugs 174.

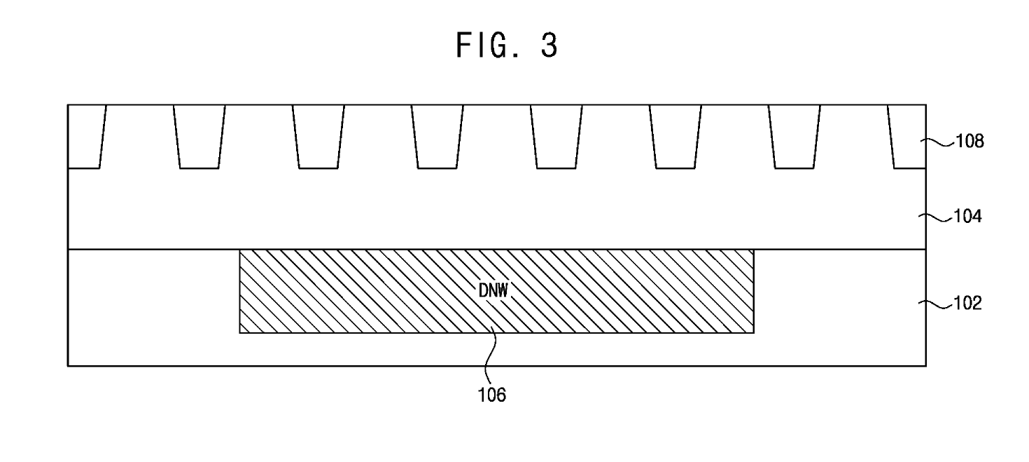

FIGS. 3 to 8 are cross-sectional views illustrating a method of manufacturing the bipolar junction transistor as shown in FIG. 1.

Referring to FIG. 3, an epitaxial layer 104 of a first conductive type, for example, a p-type epitaxial layer may be formed on a substrate 102 by an epitaxial process. A deep well region 106 of a second conductive type, for example, a DNW region may be formed in the substrate 102 by an ion implantation process. Alternatively, when a p-type substrate is used as the substrate 102, the epitaxial process may be omitted.

Further, device isolation regions 108 may be formed in surface portions of the epitaxial layer 104. The device isolation regions 108 may be used to electrically isolate an emitter 140, a base 142, a collector 144 and a well tap 146 with one another, as described with respect to FIGS. 1 and 2, above. For example, the device isolation regions 108 may have a ring shape as shown in FIG. 2 and may be formed by a shallow trench isolation (STI) process.

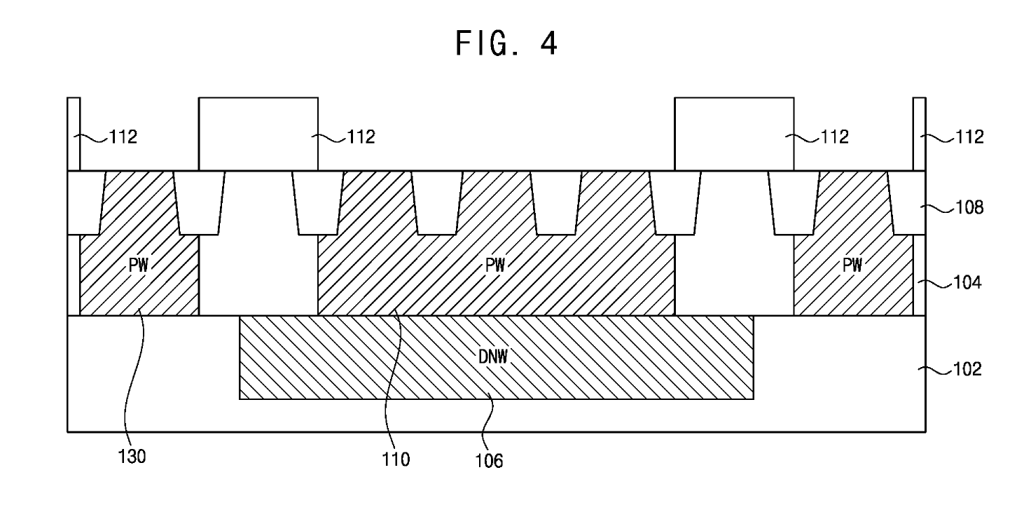

Referring to FIG. 4, a first ion implantation mask 112 may be formed on the epitaxial layer 104 in order to form a first well region 110 in the epitaxial layer 104. For example, the first ion implantation mask 112 may be a photoresist pattern formed by a photolithography process and may expose a region in which the first well region 110 will be formed. Further, the first ion implantation mask 112 may expose a region in which a third well region 130 will be formed, as shown in FIG. 4, in some embodiments.

Then, the first well region 110 of the first conductive type may be formed in the epitaxial layer 104 by an ion implantation process using the first ion implantation mask 112. For example, a PW region serving as the first well region 110 may be formed in the epitaxial layer 104. Particularly, the first well region 110 may be formed on the deep well region 106. Further, the third well region 130 of the first conductive type, for example, a second PW region may be simultaneously formed with the first well region 110 by the ion implantation process, in embodiments.

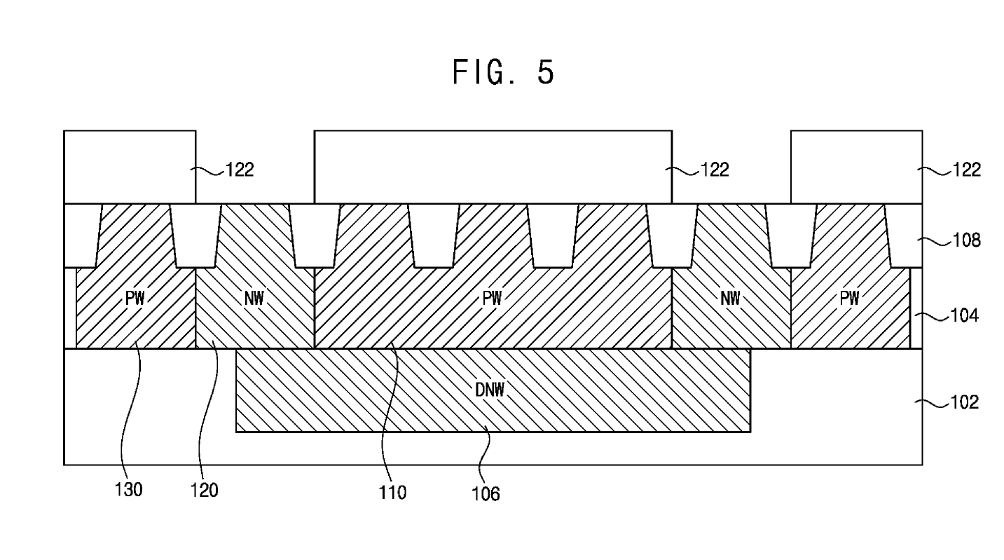

After forming the first and third well regions 110 and 130, the first ion implantation mask 112 may be removed by, for example, an ashing and/or strip process. The resultant structure forms the precursor to the device shown in FIG. 5.

Referring to FIG. 5, a second ion implantation mask 122 may be formed on the epitaxial layer 104 in order to form a second well region 120 in the epitaxial layer 104. For example, the second ion implantation mask 122 may be a photoresist pattern formed by a photolithography process and may expose a region in which the second well region 120 will be formed.

Then, the second well region 120 of the second conductive type may be formed in the epitaxial layer 104 by an ion implantation process using the second ion implantation mask 122. For example, an n-well (“NW”) region serving as the second well region 120 may be formed in the epitaxial layer 104. Particularly, the second well region 120 may be formed on the deep well region 106 so as to be electrically connected with the deep well region 106. Further, P-N junctions may be formed between the first and second well regions 110 and 120 and between the first well region 110 and the deep well region 106.

After forming the second well region 120, the second ion implantation mask 122 may be removed by, for example, an ashing and/or strip process.

Meanwhile, when the p-type substrate is used as the substrate 102, the first, second and third well regions 110, 120 and 130 may be formed in surface portions of the p-type substrate.

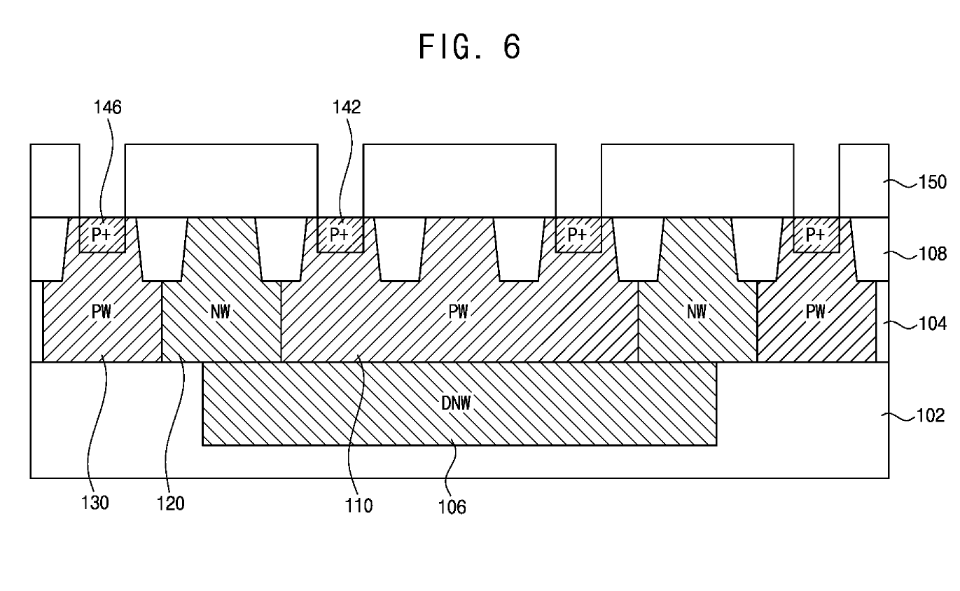

Referring to FIG. 6, a third ion implantation mask 150 may be formed on the substrate 102 in order to form the base 142 and the well tap 146 of the first conductive type. The third ion implantation mask 150 may be a photoresist pattern formed by a photolithography process and may expose portions of the first and third well regions 110 and 130 among the device isolation regions 108.

Then, an ion implantation process using the third ion implantation mask 150 may be performed so as to form the base 142 and the well tap 146 in surface portions of the first and third well regions 110 and 130, respectively. For example, high concentration p-type impurity regions capable of being used as the base 142 and the well tap 146 may be formed on the first and third well regions 110 and 130. Further, the base 142 may have a rectangular or square ring shape on the first well region 110, and the well tap 146 may have a rectangular or square ring shape on the third well region 130. Particularly, the base 142 and the well tap 146 may be spaced apart from the device isolation regions 108. As described previously, non-square, rounded, or even irregular patterns could be used for each of these portions.

After forming the base 142 and the well tap 146, the third ion implantation mask 150 may be removed by, for example, an ashing and/or strip process.

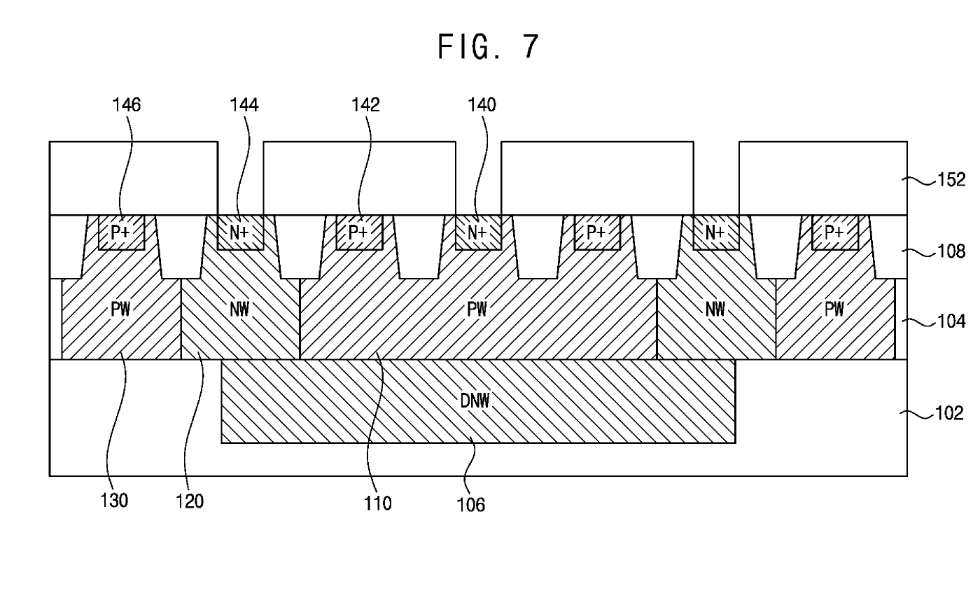

Referring to FIG. 7, a fourth ion implantation mask 152 may be formed on the substrate 102 in order to form the emitter 140 and the collector 144 of the second conductive type. The fourth ion implantation mask 152 may be a photoresist pattern formed by a photolithography process and may expose portions of the first and second well regions 110 and 120 among the device isolation regions 108.

Then, an ion implantation process using the fourth ion implantation mask 152 may be performed so as to form the emitter 140 and the collector 144 in surface portions of the first and second well regions 110 and 120, respectively. For example, high concentration n-type impurity regions capable of being used as the emitter 140 and the collector 144 may be formed on the first and second well regions 110 and 120. Further, the emitter 140 may be formed inside the base 142, and the collector 144 may be formed in a rectangular or square ring shape between the base 142 and the well tap 146. Particularly, the emitter 140 and the collector 144 may be spaced apart from the device isolation regions 108.

After forming the emitter 140 and the collector 144, the fourth ion implantation mask 152 may be removed by, for example, an ashing and/or strip process.

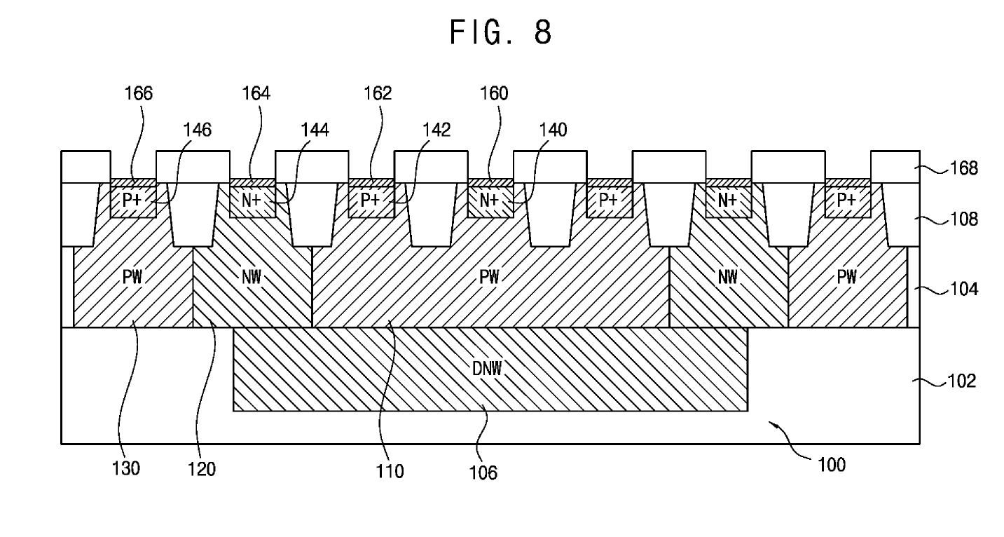

Referring to FIG. 8, a silicide-blocking layer 168 may be formed on the substrate 102 in order to form metal silicide patterns 160, 162, 164 and 166. The silicide blocking layer 168 may have openings exposing the emitter 140, the base 142, the collector 144 and the well tap 146. For example, the silicide blocking layer 168 may be made of silicon oxide or silicon nitride and may be formed by a chemical vapor deposition process. Further, the opening may be formed by an anisotropic etching process.

After forming the silicide blocking layer 168, a metal silicidation process may be performed so as to form first, second, third and fourth metal silicide patterns 160, 162, 164 and 166 on the emitter 140, the base 142, the collector 144 and the well tap 146, respectively. For example, cobalt silicide patterns capable of being used as the first, second, third and fourth metal silicide patterns 160, 162, 164 and 166 may be formed on the emitter 140, the base 142, the collector 144 and the well tap 146. Particularly, the first, second, third and fourth metal silicide patterns 160, 162, 164 and 166 may be spaced apart from the device isolation regions 108.

For example, a metal layer (not shown) may be formed on the silicide-blocking layer 168 and the exposed emitter, base, collector and well tap 140, 142, 144 and 146, and a heat treatment process may then be performed so as to form the first, second, third and fourth silicide patterns 160, 162, 164 and 166. After performing the metal silicidation process, the remaining portions of the metal layer and the silicide-blocking layer 168 may be removed by a wet etching process or an etch-back process.

Further, after removing the remaining portions of the metal layer and the silicide-blocking layer 168, the insulating layer 170, the contact plugs 174 and the metal wiring layer 172 may be formed as shown in FIG. 1.

In accordance with exemplary embodiments of the present invention as described above, a bipolar junction transistor 100 may include a first well region 110 of a first conductive type and a second well region 120 of a second conductive type. An emitter 140 and a base 142 may be formed on the first well region 110, and a collector 144 may be formed on the second well region 120. Further, device isolation regions 108 may be disposed among the emitter 140, the base 142 and the collector 144. Particularly, the emitter 140, the base 142 and the collector 144 may be spaced apart from the device isolation regions 108.

As described above, because the emitter 140, the base 142 and the collector 144 are spaced apart from the device isolation regions 108, the electrical noise of the bipolar junction transistor 100, which may be caused by the STI induced stress, may be significantly reduced. Further, the electrons trapped in trap sites on side surfaces of the device isolation regions 108 may be reduced, and thus the electron mobility may be improved between the emitter 140 and the collector 144. As a result, the current gain (hfe) of the bipolar junction transistor 100 may be significantly improved.

Although the bipolar junction transistor 100 and the method of manufacturing the same have been described with reference to the exemplary embodiments, they are not limited thereto. Therefore, it will be readily understood by those skilled in the art that various modifications and changes can be made thereto without departing from the spirit and scope of the present invention defined by the appended claims.

Various embodiments of systems, devices, and methods have been described herein. These embodiments are given only by way of example and are not intended to limit the scope of the claimed inventions. It should be appreciated, moreover, that the various features of the embodiments that have been described may be combined in various ways to produce numerous additional embodiments. Moreover, while various materials, dimensions, shapes, configurations and locations, etc. have been described for use with disclosed embodiments, others besides those disclosed may be utilized without exceeding the scope of the claimed inventions.

Persons of ordinary skill in the relevant arts will recognize that the subject matter hereof may comprise fewer features than illustrated in any individual embodiment described above. The embodiments described herein are not meant to be an exhaustive presentation of the ways in which the various features of the subject matter hereof may be combined. Accordingly, the embodiments are not mutually exclusive combinations of features; rather, the various embodiments can comprise a combination of different individual features selected from different individual embodiments, as understood by persons of ordinary skill in the art. Moreover, elements described with respect to one embodiment can be implemented in other embodiments even when not described in such embodiments unless otherwise noted.

Although a dependent claim may refer in the claims to a specific combination with one or more other claims, other embodiments can also include a combination of the dependent claim with the subject matter of each other dependent claim or a combination of one or more features with other dependent or independent claims. Such combinations are proposed herein unless it is stated that a specific combination is not intended.

Any incorporation by reference of documents above is limited such that no subject matter is incorporated that is contrary to the explicit disclosure herein. Any incorporation by reference of documents above is further limited such that no claims included in the documents are incorporated by reference herein. Any incorporation by reference of documents above is yet further limited such that any definitions provided in the documents are not incorporated by reference herein unless expressly included herein.

For purposes of interpreting the claims, it is expressly intended that the provisions of 35 U.S.C. §112(f) are not to be invoked unless the specific terms “means for” or “step for” are recited in a claim.

1. A bipolar junction transistor comprising:
a first well region having a first conductive type;
a second well region disposed adjacent to the first well region and having a second conductive type;
an emitter disposed on the first well region and having the second conductive type;
a base disposed on the first well region and having the first conductive type;
a collector disposed on the second well region and having the second conductive type; and
device isolation regions disposed among the emitter, the base and the collector,
wherein the emitter, the base and the collector are spaced apart from the device isolation regions.

2. The bipolar junction transistor of claim 1, further comprising:
a first metal silicide pattern disposed on the emitter;
a second metal silicide pattern disposed on the base; and
a third metal silicide pattern disposed on the collector.

3. The bipolar junction transistor of claim 2, wherein the first metal silicide pattern has a width equal to or smaller than that of the emitter.

4. The bipolar junction transistor of claim 2, wherein the second metal silicide pattern has a width equal to or smaller than that of the base.

5. The bipolar junction transistor of claim 2, wherein the third metal silicide pattern has a width equal to or smaller than that of the collector.

6. The bipolar junction transistor of claim 1, wherein the base has a ring shape surrounding the emitter, and the collector has a ring shape surrounding the base.

7. The bipolar junction transistor of claim 1, further comprising a deep well region having the second conductive type,
wherein the first and second well regions are disposed on the deep well region.

8. The bipolar junction transistor of claim 1, further comprising:
a third well region disposed adjacent to the second well region and having the first conductive type; and
a well tap disposed on the third well region and having the first conductive type.

9. A method of manufacturing a bipolar junction transistor comprising:
forming device isolation regions on a substrate;
forming a first well region having a first conductive type on the substrate;
forming a second well region having a second conductive type on the substrate to be adjacent to the first well region;
forming a base having the first conductive type on the first well region; and
forming an emitter and a collector having the second conductive type on the first and second well regions, respectively,
wherein the emitter, the base and the collector are formed among the device isolation regions to be spaced apart from the device isolation regions.

10. The method of claim 9, wherein the base has a ring shape surrounding the emitter, and the collector has a ring shape surrounding the base.

11. The method of claim 9, further comprising forming metal silicide patterns on each of the emitter, the base and the collector.

12. The method of claim 11, wherein the metal silicide patterns are spaced apart from the device isolation regions.

13. The method of claim 9, further comprising forming a deep well region having the second conductive type in the substrate,
wherein the first and second well regions are formed on the deep well region.

14. The method of claim 9, further comprising forming an epitaxial layer having the first conductive type on the substrate,
wherein the first and second well regions are formed in the epitaxial layer.

15. The method of claim 9, wherein the substrate has the first conductive type, and the first and second well regions are formed in surface portions of the substrate.

16. The method of claim 9, further comprising:
forming a third well region having the first conductive type on the substrate to be adjacent to the second well region; and
forming a well tap having the first conductive type on the third well region,
wherein the third well region is simultaneously formed with the first well region, and the well tab is simultaneously formed with the base.
